(19) United States
(12) Patent Application Publication
(10) Pub. No.: US 2010/0078312 A1
(43) Pub. Date: Apr. 1, 2010

(54) Sputtering Chamber Having ICP Coil and Targets on Top Wall

(75) Inventors: Ravi Mullapudi, San Jose, CA (US); Biju Ninan, Cupertino, CA (US); Gabriel A. Calebotta, Cupertino, CA (US)

Correspondence Address: PATENT LAW GROUP LLP, 2635 NORTH FIRST STREET, SUITE 223, SAN JOSE, CA, 95134, US

(73) Assignee: Tango Systems, Inc., San Jose, CA (US)

(21) Appl. No.: 12/239,659

(22) Filed: Sep. 26, 2008

(51) Int. Cl. C23C 14/34

(52) U.S. Cl. 204/192.12; 204/298.01

(57) ABSTRACT

A vacuum chamber has multiple wafer positions, and the wafers are positioned by a rotating pallet. Above a wafer position in the chamber there may be a sputtering target, a flat inductively coupled plasma (ICP) coil for etching the wafer and/or promoting sputtering, and a TEOS vapor outlet for forming an oxide film on the wafer. As the pallet rotates, a wafer may first have deposited a thin layer of oxide on walls of a via hole at the TEOS position. A metal layer may then be sputtered in the via hole at the sputtering position, and any pinch-off material may be etched away at an etching position. A magnet behind each target scans back and forth behind the target. Vertical magnet walls substantially surround a sputtering target for confining the sputtered material to an angle that is more normal to the wafer than prior art trajectories to fill narrower vias.

### CROSS-REFERENCE TO RELATED APPLICATIONS

This application relates to the application entitled “Confining Magnets in Sputtering Chamber,” by Ravi Mullapudi et al., filed concurrently with the present application.

### FIELD OF THE INVENTION

This invention relates to deposition systems for semiconductor wafers and other workpieces and, in particular, to sputtering systems.

### BACKGROUND

The present assignee, Tango Systems, Inc., had created a multi-wafer sputtering system having magnets that scanned back and forth behind a target. That system is described in United States Patent Publication US 2006/0231383 A1, incorporated herein by reference. The present invention improves on such a system and other sputtering systems.

A sputtering system is widely used for depositing thin films on workpieces, such as semiconductor wafers, LCD panels, and other surfaces. Sputtering is sometimes referred to as physical vapor deposition, or PVD. In a sputtering operation, thin films, such as Al, Au, Cu, or Ta, are deposited in a vacuum on silicon wafers or other substrates.

It is common to form conductive vias through one or more insulating layers on a silicon wafer for electrically coupling different metal layers formed over the wafer, or the vias may extend completely through the silicon wafer itself. A via may extend from a top metal layer to a backside electrode formed on the bottom of the wafer. After the wafer is diced, a die can then be bonded directly on a printed circuit board (PCB), and a second die can be mounted over the first die, where the vias electrically connect semiconductor components on both dies to the PCB.

It is desirable to make the vias as narrow as possible to use a minimum of surface area. The via hole diameter may be less than 0.2 micron. It is difficult to fill such a narrow via hole with metal. Any discontinuity in the metal filling or coating a via hole causes the chip to be defective.

FIG. 1 is a cross-section of a portion of the sputtering chamber described in Tango System's US 2006/0231383 A1, where the thickness dimension of the wafer is greatly exaggerated for illustration. The chamber is sealed to create a low pressure, such as 20 millitorr or below.

In FIG. 1, a silicon wafer 10 is placed on a rotating metal pallet 12, such as an aluminum pallet. The wafer 10 has etched in it very narrow via holes 13 whose walls are intended to be entirely coated with Cu in the sputtering process. The via hole walls are oxidized to create a thin insulating layer. Above the wafer 10 is a target 14 formed of Cu or any other suitable material for sputtering. The target 14 is secured to a backing plate 16, forming a portion of a top wall of the chamber. Above the backing plate 16, outside of the chamber, is a magnetron comprising a scanning magnet 18 that scans back and forth over the target 14 in an arc.

Argon gas is introduced into the chamber. To create a plasma 19 (ionized Ar atoms), a high DC bias potential is applied between the pallet 12 and the target 14, and/or an RF voltage is applied between the pallet 12 and the target 14, and/or an RF current is supplied through a coil around the chamber. The electric or magnetic field created ionizes the argon atoms, and a current flows through the ionized atoms and the free electrons in the plasma. The target 14 is negatively biased and attracts the Ar+ ions. The scanning magnet 18 increases the plasma density at the target 14. The high energy Ar ions impacts the Cu target 14 to dislodge Cu atoms 20, which move through the chamber at all angles. Applicant's chamber is relatively large since there may be up to five separate targets and five wafers on the rotating pallet. As a result, the Cu atoms impact the wafer 10 at a wide variety of angles and also miss the wafer altogether. The Cu forms a layer 22 over the wafer 10.

The Cu atoms impacting the wafer 10 at an angle build up at the entrance to each via hole 13 and progressively close off the via hole opening (called pinch-off). If the via hole diameter is small enough, the opening will be sufficiently pinched off so that Cu atoms cannot reliably coat the walls of the via hole. As a consequence of this, via hole openings must be kept sufficiently large or the via holes must be made conical.

Additionally, the widely sputtered material is also deposited on the chamber walls, requiring cleaning.

What is needed is a sputtering technique that causes the target material to be sputtered more normal to the wafer surface so that there is less pinch-off at the opening of a narrow via hole. Such a technique would enable via hole openings to be made very small (e.g., 0.1 micron), increase yield, and more efficiently utilize the target material.

It is also desirable to perform multiple processing steps on the via hole, such as sputtering, depositing SiO₂ using TEOS (tetraethyl orthosilicate), and etching, in a single chamber to limit the transport of the wafer between various processing chambers.

### SUMMARY

To confine the sputtered ions to an area over the workpiece and to direct the sputtered ions in a more normal path relative to the workpiece surface, a vertical wall of stacked permanent magnets is positioned around a target within the sputtering chamber. The magnets may be coated with a dielectric layer, such as a ceramic to prevent etching of the magnets and contamination.

An inductively coupled plasma (ICP) is formed in the chamber using a helical coil around the chamber or a flat coil in or above the chamber. ICP is a type of plasma in which the energy of the gas (e.g., Ar) is supplied by electrical currents produced by electromagnetic induction at radio frequencies (RF).

Scanning magnets above the one or more targets increase the plasma density at the targets. The energized Ar atoms impact the target, such as a Cu target, and a large proportion (e.g., greater than 25%) of the dislodged Cu atoms are Cu+ ions. The wafer (or other workpiece) is negatively biased via a bias on the supporting metal pallet. The vertical wall of magnets surrounding the target effectively repels the Cu+ ions, and the negative bias on the wafer attracts the Cu+ ions. The combination of the confining magnetic field surrounding the target and the bias on the wafer causes the Cu atoms to impact the wafer at an average angle that is more normal to the wafer compared to prior art techniques.

The steeper angle of the sputtered material results in less pinch-off of the opening of via holes so the walls of the via holes are completely coated with the sputtered material.

The vertical magnet wall surrounding the target also reduces waste of the target material (including deposition on the chamber walls) since the sputtered material is confined by the magnetic walls and impacts the wafer.

Surrounding the target by a vertical wall of magnets within the chamber provides significant benefits over locating auxiliary magnets outside of the chamber. If auxiliary magnets were just located surrounding the chamber, the field created would not evenly affect the sputtered material, since different areas of the target are located at widely different distances from the auxiliary magnets. Accordingly, the wafer would not be evenly coated with the sputtered material. Further, locating auxiliary magnets around the outside of the chamber, relatively far from the target, does not confine the sputtered material to the wafer area or significantly confine the angle of impact, since the auxiliary magnets do not have a strong confining effect on the ions. Further, with auxiliary magnets located outside the chamber, the areas near multiple targets in the chamber experience different effects from the magnetic fields.

In one embodiment, there are multiple targets in the chamber, each with its associated scanning magnet. The characteristics of the vertical walls of magnets surrounding each target are adjusted so the trajectories of the sputtered material for each target are controlled based on the needs of the application. For example, wide angles of impact may be needed in certain applications for step coverage.

In another embodiment, the sputtering chamber has multiple wafer positions (or stations), determined by the angular position of a rotating pallet that supports multiple wafers. A sputtering target is above at least one of the positions. Above another of the positions is a flat ICP coil that creates a high energy Ar plasma only substantially below that position, which is a wafer etching position. Any excess material sputtered on the wafer at one of the sputtering positions is etched at the etching position after the pallet is rotated to avoid requiring the wafer to be transported to a separate etching chamber. Thus, any pinching off of a via opening by sputtered material may be etched away, followed by another sputtering step to further fill in the via. The shape of the ICP coil is semi-triangular so as to create a uniform etch of the wafer as the pallet continuously rotates under the etching position, since different areas of the wafer have different velocities through the etching position. In the preferred embodiment, the ICP coil is protected by a dielectric layer, and the ICP coil may be outside the vacuum of the chamber, to prevent material from the coil contaminating the wafers.

In another embodiment, one of the positions in the chamber is a TEOS oxide deposition position for depositing a thin oxide film in via holes or on any wafer surface. After a wafer has its via hole walls coated with oxide, the wafer is rotated to a sputtering position to receive a coating of material over the oxide. The wafer may then be rotated to the etching position for removing any pinch-off material. In this way, vias in multiple wafers may be processed without removing wafers from a chamber. In one embodiment, the pallet is continuously rotating to achieve even deposition of material.

In another embodiment, two targets of the same material are tilted inwardly toward their midpoint, and an ICP coil is between the two targets. Angling the targets causes a higher percentage of the target material to impact the wafer at an angle, approximately normal to the target surface. Since the two targets are angled with an opposite tilt, the sputtered material can better coat the sides of vias as the wafers are rotated on the pallet during the sputtering operation. Further, since the wafers are rotating, the oppositely tilted targets create a more symmetrical sputtering on the inner via walls. The sputtered material can even coat frustum shaped vias. The coil creates a symmetrical plasma density in front of the targets for sputtering and may also be used for etching.

Any type of workpiece, or any shape, may be used instead of wafers.

### BRIEF DESCRIPTION OF THE DRAWINGS

FIG. 1 is a simplified cross-sectional view of the sputtering chamber in United States Patent Publication US 2006/0231383 A1, assigned to Tango Systems, Inc., illustrating the sputtered material pinching off openings of very narrow via holes.

FIG. 2 is a perspective cut-away view of the sputtering chamber of US 2006/0231383 A1, augmented by the present invention. Multiple wafers are positioned under the targets while a wafer pallet rotates.

FIG. 3 is a cross-sectional view of a portion of the modified sputtering chamber in accordance with one embodiment of the present invention, showing a vertical magnetic wall within the chamber substantially surrounding the target, where the magnetic wall confines sputtered material and causes the average angle of impingement onto the wafer to be more normal to the wafer surface.

FIG. 4 is a cross-sectional view of the modified sputtering chamber similar to that of FIG. 3 but having a different arrangement of magnets in the confining magnetic wall.

FIG. 5 is a bottom up view of multiple targets in the chamber for sputtering, showing a magnetic wall around two targets, and an ICP coil at one position for etching sputtered material below the coil.

FIG. 6 is a bottom up view of the chamber, showing a TEOS deposition position, a sputtering position, and an etching position within the chamber. The chamber may include any number and combination of TEOS positions, sputtering positions, and etching positions.

FIG. 7 is a bottom up view of the chamber, showing an ICP coil between targets of the same material where the targets are tilted toward the midpoint for better coverage as the wafers are rotating on the pallet.

FIG. 8 is a partial cross-sectional view along line 8-8 in FIG. 7, showing the ICP coil, the tilting of the targets, and the movement of a wafer on the pallet.

FIG. 9 is a cross-sectional view of a die containing semiconductor components and conductive vias, where the vias provide a conductive path between topside and bottomside electrodes of the die. A second die is bonded to the topside vias, and the bottomside vias are bonded to a printed circuit board.

Elements labeled with the same numbers in the various figures are the same or similar.

### DETAILED DESCRIPTION

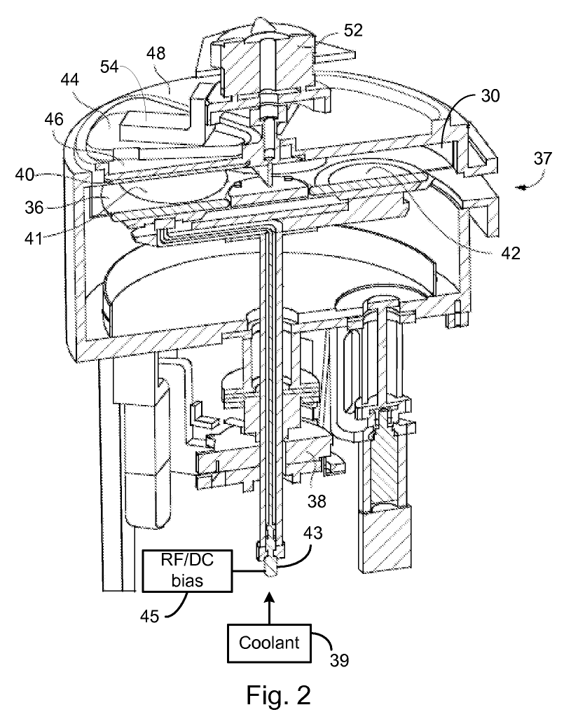

FIG. 2 illustrates a process chamber 30. Inside the chamber 30 is a rotating pallet 36 that may be formed of aluminum. The wafers 41, or other workpieces, are loaded onto the pallet 36, via an opening 37 into the chamber, by a robotic arm. A motor 38 rotates the pallet 36. Pallet 36 may be continuously rotated at any speed during processing of the wafers or may be temporarily stopped at a position to control the deposition of a sputtered material from a target 40 overlying a wafer. A wafer 41 is shown in one of five wafer supporting areas 42. The entire back surface of each wafer is in electrical and thermal contact with pallet 36.

The wafer is cooled by controlling a coolant flowing through a table supporting the pallet 36, described in detail in United States Publication US 2006/0231383 A1. The coolant source 39 is connected to an inlet 43 of a metal coolant pipe. The pallet 36 may also be equipped with resistive heaters to heat the wafers if desired.

An RF (e.g., 13.56 MHz) source and DC bias source are electrically coupled to the pallet 36 (and thus coupled to the wafers) for creating a plasma and attracting ionized sputtered atoms. In another embodiment, pallet 36 is grounded, floated, or biased with only a DC voltage source. The RF and DC bias source 45 are external to the chamber and electrically contact the pallet 36 via the metal coolant pipe.

The chamber 30 wall is typically electrically grounded during processing operations.

When the chamber 30 is evacuated and back filled with Ar gas at a certain pressure (for example, 20 millitorr) and the gas is energized by a DC source, an RF source, or a combination of the two sources, an electromagnetic field is created inside chamber 30 to excite a sustained high density plasma near the target 40 surface. The plasma confined near the target surface (described later) contains positive ions (Ar+) and free electrons. The ions in the plasma strike the target surface and sputter material off the target. The wafer under the target receives the sputtered material to form a deposited layer on the surface of the wafer. In one instance, up to twenty kilowatts of DC power can be provided on each target. In such a case, each target can deposit approximately 1 micron per minute of copper, simultaneously, on multiple workpieces.

The Ar gas may be introduced into the chamber 30 using any conventional gas inlet device. In a preferred embodiment, the chamber gas is provided by a distribution channel at the bottom of the chamber 30, rather than from the top, which reduces particle contamination during the sputtering process and allows optimization of the magnetron assembly.

A bias voltage on the wafers can drive a flux of an electrically charged species (Ar+ and/or atomic vapor sputtered off the target) to the wafers. The flux can modify the properties (e.g., deposition rate) of the sputtered material to the wafers.

Generating a plasma for sputtering and the various biasing schemes are well known, and any of the known techniques may be implemented with the described sputtering system.

The chamber 30 uses a magnetron assembly, outside the vacuum, to further control the bombardment of the target by the plasma. In a typical conventional system, a fixed permanent magnet is located behind the target so that the plasma is confined to the target area. The resulting magnetic field forms a closed-loop annular path acting as an electron trap that reshapes the trajectories of the secondary electrons ejected from the target into a cycloidal path, greatly increasing the probability of ionization of the sputtering gas within the confinement zone. Inert gases, specifically argon, are usually employed as the sputtering gas because they tend not to react with the target material or combine with any process gases and because they produce higher sputtering and deposition rates due to their high molecular weight. Positively charged argon ions from the plasma are accelerated toward the negatively biased target and impact the target, resulting in material being sputtered from the target surface.

FIG. 2 illustrates one of the three magnets 44 overlying a target backing plate 46, where the backing plate 46 is supported by a grounded top plate 48. Magnet 44 has a substantially triangular or delta shape with rounded corners. In one embodiment, the thickness of magnet 44 is between 0.5-1¼ inch thick (12-31 mm). More detail of the magnets 44 can be found in US 2006/0231383 A1.

Magnet 44 is shown above a target 40, such as Cu. Two other identical magnets would be located above two other targets centered at 120 degree intervals. An actuator 52, such as a servo motor or other type of actuator, oscillates the three magnets 44 back and forth in unison over their associated targets at an oscillating period of between 0.5-10 seconds. The magnets 44 are oscillated so that the magnetic fields are not always at the same position relative to the target. By distributing the magnetic fields evenly over the target, target erosion is uniform.

An insulating bracket 54 secures each magnet 44 to actuator 52 so that there is a minimum gap between the oscillating magnet 44 and the target backing plate 46.

Since there is no field in the middle portion of magnet 44, the magnet 44 must scan a distance of at least half its width (and preferably almost its entire width) so that the middle portion of the target experiences the same magnetic fields as other portions of the target.

The size of magnets 44 depends on the size of the wafers, which determines the size of the targets. In one embodiment, a magnet 44 is about 10.7 inches (27 cm) long and about 3 inches (7.6 cm) wide at it widest part. An eight inch wafer may use a target that is from 10-13 inches long in the radial direction. A twelve inch wafer may use a target that is from 13-18 inches long in the radial direction. These target and magnet length dimensions are very small compared to the typical prior art. These small dimensions result in a more efficient use of the chamber volume, thus a smaller system footprint and lower costs for the targets and system. Generally, the target and magnet length perpendicular to the scanning direction is between 1.1 and 1.5 times the smallest dimension of the workpiece surface facing the target.

The target backing plate 46 and the target 40 are electrically connected to a negative bias voltage source in order for the plasma to be concentrated in the area of the target 40. The target 40 is sometimes referred to as the cathode, since it is negatively biased. The top plate 48, supporting and insulated from the target backing plate 48, is electrically grounded. An insulator ring (e.g., a synthetic rubber ring, or other elastic material) electrically insulates the target backing plate 46 from the grounded portion.

The distance between magnet 44 and target 40 should be small to maximize the magnetic coupling to the target 40. In one embodiment, the distance is between 0.5-0.75 inch (12.7-19 mm).

In another embodiment, there are five or more targets, each at a different position on the upper wall of the chamber.

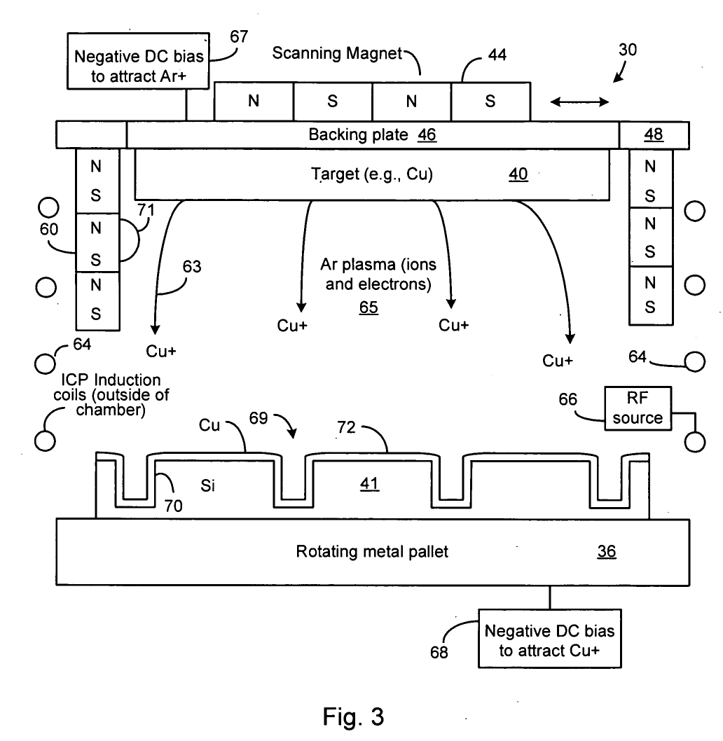

The system of FIG. 2 is augmented with the features described below, shown in detail in FIGS. 3-6.

FIG. 3 is a cross-sectional view of a portion of the chamber 30 and magnetron, illustrating a vertical wall of magnets 60 surrounding or partially surrounding the targets 40. The magnets 60 may be grounded since they are supported by the top plate 48. The magnets may be affixed to the top plate 48 by any suitable bracket and may be coated with a suitable non-etchable layer, such as an oxide or a ceramic. There may be any number of magnets making up the wall.

The magnets 60 may extend down to about 5-10 mm above the wafer. The distance between a target and a wafer may be between 50-150 mm, so the magnetic wall will typically range between 40-145 mm. The magnetic wall should exhibit a flux about 1%-10% as powerful as the scanning magnets behind the targets. The scanning magnet flux may be between 600-2000 gauss one inch away, and the magnetic wall flux may be 20-200 gauss one inch away. Ideally, the magnetic wall should completely encircle a target and have the same properties around the target.

The wafer 41 thickness is shown greatly enhanced for illustration purposes.

A helical ICP coil 64 surrounds the outer periphery of the chamber 30, although the coil 64 is shown proximate to the magnets 60 for illustration purposes only. An RF current (e.g., at 13.56 MHz) is conducted by the coil 64 to create an Ar plasma 65 in which the energy of the plasma is supplied by electrical currents through the Ar ions and electrons produced by electromagnetic induction by the coil 64. The RF power may be on the order of 500 watts up to a few kW. In another embodiment, a flat coil inside or outside of the chamber 30 may be used to generate the ICP. More detail about creating an ICP and other plasma creation techniques for a sputtering chamber may be found in International Publication Number WO 03/042424 A1, assigned to Applied Materials and incorporated herein by reference.

The target 40 is biased with a negative DC voltage of about −200 to −600 volts, and the wafer 41 is biased at a less negative voltage of about −30 volts. The combination of the magnetic field created by the scanning magnet 44 and the negative bias on the target 40 causes energized Ar atoms to impact the target 40 and dislodge Cu atoms, a significant percentage (e.g., 30%) being Cu+ ions 63. Shown are the coil 64 RF source 66, the target DC bias source 67, and the wafer DC bias source 68. RF may also be coupled between the target and wafer.

The via holes 69 are formed in the silicon wafer 41 by conventional masking and etching steps outside of the chamber 30. A thin oxide layer 70 is grown or deposited on the walls of the via holes 69, typically outside the chamber 30. The via holes 69 may instead be holes formed in an insulating layer.

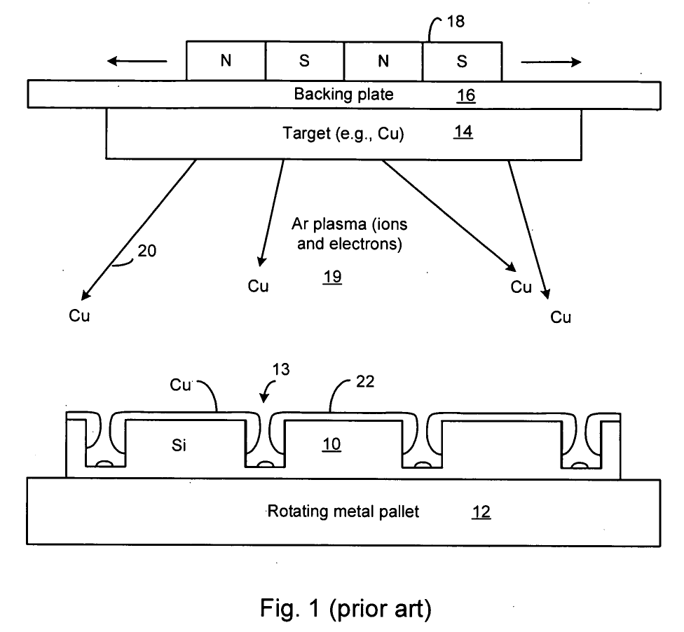

Normally, without the vertical magnets 60, the Cu atoms will have a wide angle of trajectories when impacting the wafer 41, as shown in prior art FIG. 1. Without the vertical magnets 60 substantially surrounding the target 40, the low angle Cu atoms will quickly pinch off the opening of narrow via holes 69. As shown in FIG. 3, the magnets 60 create vertical magnetic fields (e.g., magnetic field line 71) around the target 40 that repel the Cu atoms and thus confines them to the area of the wafer 41. The combined repulsion forces from the surrounding magnetic walls cause the Cu atoms to impact the wafer 41 at an angle that is more normal than had the vertical magnets 60 not been used. This reduces the pinch-off build up and allows the via holes 69 to have narrower openings than in the prior art. FIG. 3 shows the sputtered copper 72 evenly coating the sidewalls and bottom of the via holes 69, which may have a diameter as little as 0.1 micron or less. Further, the via holes 69 may be made deeper than the via holes in the prior art due to the more normal trajectories of the Cu atoms. The thin oxide layer 70 insulates the Cu from the Si wafer 41.

Additionally, the magnetic wall also creates a higher electron density between the target and the wafer for increased deposition rate and prevents electrons and ions from contacting the grounded wall of the chamber and becoming wasted.

Some examples of thin films that may be sputtered include Al, Cu, Ta, Au, Ti, Ag, Sn, NiV, Cr, TaNx, Hf, Zr, W, TiW, TiNx, AlNx, AlOx, HfOx, ZrOx, TiOx, and alloys of two or more of these materials.

Prior art techniques sometimes separate the target from the wafer by a relatively large distance so that only the sputtered material on an angle substantially normal to the wafer contacts the wafer. Using the vertical magnets 60 surrounding the target enables the distance between the target and wafer to be reduced and conserves the sputtered material.

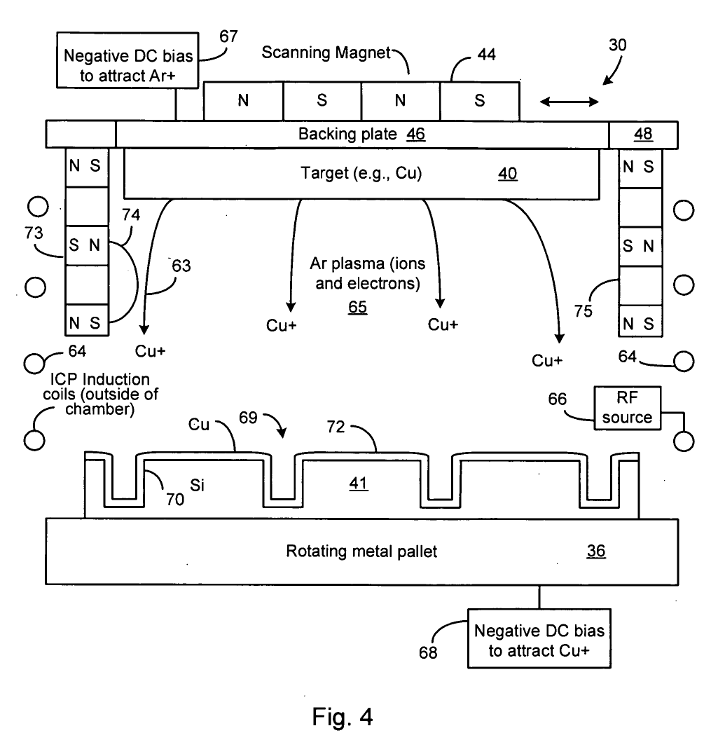

FIG. 4 illustrates a modification of FIG. 3 where the vertical wall of magnets 73 comprises magnets where the north-south poles are arranged horizontally, and the magnetic field lines 74 extend between the north and south poles of adjacent magnets. The magnets 73 are separated by air or another insulator 75 to increase the field lines.

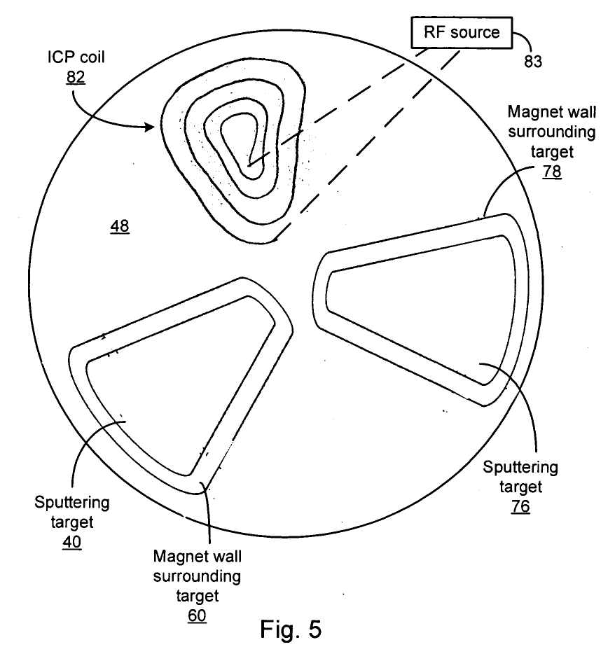

FIG. 5 is a bottom up view of the top plate 48 supporting the targets 40 and 76. Targets 40 and 76 may be different materials, such as a barrier metal (Ti or TaN) and a seed metal (Cu). The magnetic wall 60 (or 73) is shown surrounding the target 40. A different magnetic wall 78 surrounds target 76. The height and strength of the magnetic wall 78 may be different from that of wall 60 to vary the effects produced by the walls, such as due to the particular materials being sputtered. There may be any number of targets, and all or only one may employ the vertical magnetic wall surrounding the target. The magnetic wall need not completely encircle the target. For example, a magnetic wall may just be formed along the long sides of the target and the side facing the chamber wall.

FIG. 5 also illustrates that, instead of a target at a position, a flat ICP coil 82 may be formed on an electrically insulating portion of the top plate 48. The coil 82 may be at a lower position than the targets to be closer to the wafer for more efficient etching. After a sputtering step, the large ICP coil 64 (FIG. 3) surrounding the chamber is turned off, and an RF current is supplied through the coil 82 by an RF source 83 external to the chamber. This causes an ICP of Ar to be formed locally. There is no scanning magnet above the coil 82, so the Ar ions are not attracted to the top of the chamber but impact the negatively biased wafer to etch a thin layer of the sputtered material. The duration of the etching, the materials being etched, the Ar pressure, the coil 82 distance above the wafer, and the RF power determine the amount of etching. This etching enables any sputtered material pinching off a via hole opening to be removed, followed by another sputtering step to coat the lower sidewall and bottom of the via hole.

If the coil 82 is inside the chamber and not protected by a dielectric (e.g., a ceramic coating), the coil 82 may be formed of the same metal as the target to prevent contamination. More preferably, the coil 82 is outside of the chamber vacuum and separated from the chamber by a dielectric wall to avoid any sputtered particles contacting the coil itself or etching of the coil.

In one embodiment, the wafers are continually rotated by the pallet 36 (FIG. 2) during the etching process to ensure a very even etch across the wafer. In another embodiment, the wafer is temporarily stopped at the etching position. If the wafers are continually rotating around the chamber's central axis, the outer edge of the wafers will have a velocity faster than the velocity of the inner edge of the wafer nearer the chamber's central axis. Therefore, to cause an equal etch over the entire wafer, the ICP coil 82 is substantially triangularly shaped, as shown in FIG. 5. For a 12 inch wafer, the coil 82 has a dimension of about 16 inches in the radial direction.

There may be multiple etching positions and multiple sputtering positions in chamber 30.

The pallet 36 may be rotated in one direction then rotated in the other direction, if needed to provide symmetrical processing of the wafers.

While the pallet 36 is rotating and the wafers are sequentially subjected to the sputtering positions and etching positions, the via holes are being coated and the pinch-off material is being removed. The etching primarily etches the sputtered material on the wafer surface and the pinch-off material at the via hole openings and does not significantly etch deep within the via holes. Accordingly, very narrow and deep via holes may be coated with a sputtered material without the openings becoming pinched off.

In normal via processing, the wafer is masked and etched outside of chamber 30 to form the vias and any other features (e.g., trenches) that are to be filled or coated with a sputtered material. This may be part of a dual-damescene process. Only vias will be discussed for simplicity. The vias are then coated with a thin layer of oxide to insulate the subsequently sputtered material from the Si wafer. This may be done in a conventional TEOS (tetra-ethyl-ortho-silicate) process in a separate chamber that deposits oxide on a surface. The wafer then must be taken out of the TEOS chamber and transported to the sputtering chamber. It would be beneficial to perform the TEOS process in the same chamber as the sputtering process so as not to break the vacuum on the wafer and to save time.

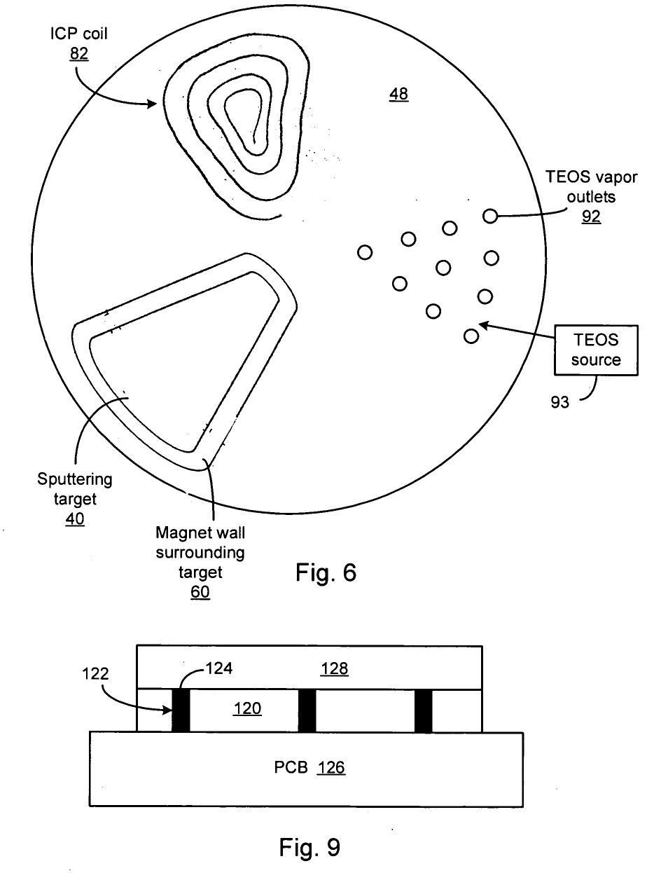

FIG. 6 is a bottom up view of the top wall of the sputtering chamber 30 showing a TEOS position for forming oxide on the via hole walls, a sputtering position (using a target 40), and an etching position (using an ICP coil 82). The TEOS position consists of a showerhead 92 comprising a distributed array of gas outlets for heated TEOS vapor, from a TEOS source 93, which remains a gas at low pressures. The TEOS comprises silicon that is already oxidized and forms an oxide surface over the Si wafer and the via hole walls. TEOS is a liquid at room temperatures and may be vaporized using a bubbler and a carrier gas or heating the TEOS to form a vapor. Any wafer beneath the TEOS showerhead 92 will have formed over it an oxide layer whose thickness is determined in part by the time of exposure.

After the wafer is exposed to the TEOS position and the TEOS introduction is terminated, the pallet 36 moves to the sputtering position under target 40 (or the pallet 36 is continuously rotated) so that a layer of the target material is sputtered onto the wafer and into the via holes. The pallet 36 is further rotated to position the wafer beneath the ICP coil 82 (either located in or outside the chamber) for removal of the pinch-off sputtered material and the material on the top surface of the wafer. The etching does not remove the sputtered material inside the via hole. The TEOS gas may be stopped after the oxide is deposited, and multiple rotations of the pallet 36 may be employed for the wafer to undergo successive sputtering and etching steps, without the wafer being exposed to the atmosphere, until the via holes are sufficiently coated or filled with the sputtered material. There may be any number of wafers on a single rotating pallet 36.

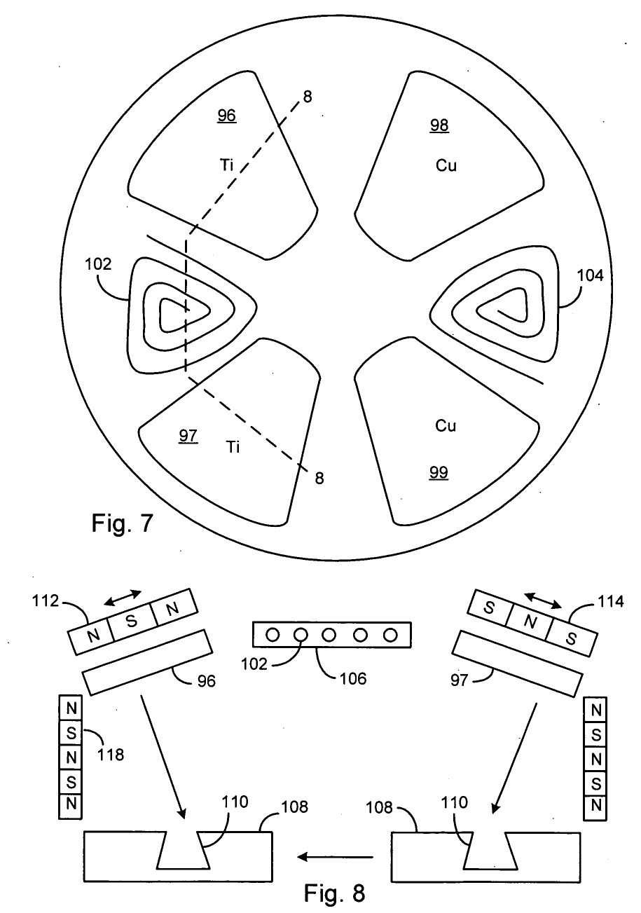

FIG. 7 is a bottom up view of the chamber illustrating targets 96 and 97 formed of the same material (e.g., titanium), and targets 98 and 99 formed of a different material (e.g., Cu). Between each pair of targets is an ICP coil 102, 104, either in the chamber of outside the chamber. If the coil 102, 104 is outside the chamber, a dielectric layer separates the coil 102, 104 from the chamber. During a sputtering operation, any coil 64 ((FIG. 3) surrounding the chamber may be energized along with energizing the coil 102, 104, or only coil 102 or 104 may be energized to localize the plasma. The coil 102/104 creates a dense ionization around it to increase the sputtering rate from its associated targets.

A vertical magnetic wall may surround each target, or a single magnetic wall may surround the pair of targets and their associated coil 102/104.

As the pallet supporting the wafers rotates, either Ti or Cu may be sputtered, depending on the energization of the coils 102 or 104, or thin layers of Ti and Cu may be successively sputtered if both coils are energized.

As mentioned before, the coils 102/104 may also be used for etching.

FIG. 8 is a cross-sectional view along line 8-8 of FIG. 7, illustrating that the targets 96, 97 may be tilted to increase the percentage of the target material impacting the wafer at an angle, approximately normal to the target surface. The ICP coil 102 is between the two targets and protected by a dielectric 106. Since the targets have an opposite tilt, the sputtered material can better coat the sides of vias as the wafers 108 are rotated on the pallet during the sputtering operation. Further, since the wafers 108 are rotating, the oppositely tilted targets create a more symmetrical sputtering on the inner via walls 110. The sputtered material can even coat frustum shaped vias. The coil 102 creates a symmetrical plasma density in front of the targets 96 and 97 for sputtering and may also be used for etching.

Preferably, the scanning magnets 112 and 114 behind each target have opposite pole configurations (shown are NSN and SNS) to more precisely offset any sputtering asymmetries from the two targets as the wafer is rotating. A single vertical wall of magnets 118 is illustrated as completely surrounding the pair of targets 96 and 97 and the coil 102 so as not to interfere with the plasma created by the coil 102. An identical wall may also surround the Cu targets 98, 99 and coil 104.

For very large workpieces, such as 18 inch diameter wafers, it may be desirable to only process one wafer at a time, since mounting a plurality of such wafers on a rotating pallet would result in a very large sputtering chamber. In such a case, the single wafer may be spun around its center axis during processing to provide uniform thin film deposition.

FIG. 9 illustrates a possible use of a die 120, separated from a wafer after processing, having insulated (e.g., coated with oxide) via holes 122 coated with a sputtered material using the system of FIG. 7. A Ti barrier layer may be formed on the insulated via walls by sputtering using the Ti targets 96 and 97 in FIG. 7, where the rotating pallet positions the wafers under the target 96, 97 and coil 102. After the barrier layer is formed, a seed layer of Cu is formed in the via holes using the Cu targets 98 and 99. After any further etching and sputtering cycles to complete the process, the wafer is removed from the chamber and the seed layer of copper is then electroplated with a much thicker layer of copper 124. The plating may completely fill the via holes, although complete filling is not required for adequate electrical conductivity. The copper seed layer (or nucleation layer) is needed for reliable plating to occur. For the plating step, the wafer is immersed in an electrolyte solution containing a copper electrode. The copper from the copper electrode then plates the copper seed layer. Chemical-mechanical polishing (or planarization), called CMP, may then be used to remove the copper over the surface of the wafer. After any further processing steps, the wafer is diced.

The chamber of FIG. 7 may also be equipped with the TEOS vapor outlets 92 (FIG. 6) to form the oxide layer in the via holes, so that there are four different processes performed on the wafers in the single process chamber,

In a dual-damascene process, copper is deposited in via holes and trenches formed in the silicon wafer. After copper plating, the wafer is then subjected to CMP to remove the copper on the surface of the wafer but not the copper in the vias or trenches. CMP is a process of smoothing and planing surfaces with the combination of chemical etching and abrasive polishing. Mechanical grinding alone may cause too much surface damage, while wet etching alone cannot attain good planarization. CMP involves both effects at the same time. A typical CMP tool consists of a rotating platen that is covered by a pad. The wafer is mounted upside down in a carrier on a backing film. Both, the platen and the carrier are rotating. During chemical mechanical polishing, pressure is applied by downward force on the carrier. An abrasive slurry is applied to the wafer. The high points on the wafer are removed and planarization is achieved. Such a process is conventional and well known.

Prior to or after plating, the backside of the wafer is grinded to remove a sufficient thickness so that the vias extend completely through the wafer. The copper 124 in the vias may be electrically connected to various semiconductor components (e.g., transistors) formed in the wafer using separate conventional processes.

The topside of the vias may be coupled to topside electrodes, and the bottomside of the vias may be couple to bottomside electrodes. The electrodes may be gold plated. After dicing, the bottomside electrodes of the die 120 may be bonded to pads on a printed circuit board 126 using ultrasonic bonding or solder. A second die 128, also containing semiconductor components, has electrodes that mate with the topside electrodes on the die 120. The electrodes on the dies 120 and 128 are then bonded to each other using ultrasonic bonding or solder. Thus, the top die 128 is electrically connected to the board 126 by the copper-filled vias in the bottom die 120, and the vias also electrically connect the circuitry in die 120 to the board 126. Die 120 may also be sandwiched between two dies.

The vias may also be formed in an insulation layer to connected between two metal layers.

Conventional aspects of the system that have not been described in detail would be well known to those skilled in the art. U.S. Pat. No. 6,630,201, U.S. Pat. No. 5,593,551, U.S. Pat. No. 6,500,762, U.S. Patent Application Publication 2002/0160125 A1, and International Patent Application Publication WO 03/056603 are incorporated herein by reference for certain aspects primarily related to creating a plasma and supplying gas to a process chamber.

Although the system has been described with respect to forming a metal film on semiconductor wafers, the system may deposit any material, including dielectrics, and may process any workpiece such as flat panel displays and solar panels. In one embodiment, the system is used to deposit materials on multiple thin film transistor arrays for LCD panels.

Having described the invention in detail, those skilled in the art will appreciate that, given the present disclosure, modifications may be made to the invention without departing from the spirit and inventive concepts described herein. Therefore, it is not intended that the scope of the invention be limited to the specific embodiments illustrated and described.

What is claimed is:

1. A multi-process device comprising:
a chamber being sealable to create a low pressure environment in the chamber;
a rotating pallet in the chamber having at least one workpiece support area for supporting a workpiece;
a target positioned on a top wall of the chamber, a front side of the target being directed into the chamber;
a magnet opposing a back side of the target; and
a substantially flat first induction coil substantially facing the pallet, the first coil being connected to an RF source for generating a localized plasma within the chamber in the vicinity of the first induction coil such that only workpieces that have been rotated to be substantially below the first induction coil are primarily affected by the localized plasma.

2. The device of claim 1 further comprising a second induction coil around the chamber for creating a plasma within the chamber for sputtering material from the target onto the workpiece when the pallet is rotated to position the workpiece below the target.

3. The device of claim 1 wherein the first induction coil only creates a plasma substantially below the first induction coil for etching material on the workpiece when the pallet has rotated to position the workpiece below the first induction coil.

4. The device of claim 1 wherein the first induction coil is located between two targets formed of the same material for generating a plasma below the two targets for sputtering material from the targets to a workpieces that has been rotated to be substantially below the targets.

5. The device of claim 4 wherein the two targets are tilted in the direction of the first induction coil to increase a percentage of sputtered target material impacting the workpiece on an angle substantially normal to a surface of the target.

6. The device of claim 1 wherein the first induction coil has a substantially triangular shape, and the target has a substantially triangular shape.

7. The device of claim 1 wherein the first induction coil is outside the chamber and separated from the chamber by a dielectric material.

8. The device of claim 1 wherein the pallet has a plurality of workpiece support areas for supporting a plurality of workpieces, wherein the pallet rotates to cause different workpieces to be under the target and the first induction coil.

9. The device of claim 1 further comprising a plurality of targets in the chamber.

10. The device of claim 1 wherein the first induction coil is closer to the pallet than the target.

11. The device of claim 1 wherein the target and first induction coil are supported by a top wall of the chamber.

12. The device of claim 1 further comprising a source of TEOS gas and a TEOS gas outlet in the chamber coupled to the TEOS gas source, the TEOS gas outlet for depositing an oxide over a surface of the workpiece when the pallet has rotated to position the workpiece below the TEOS gas outlet, such that the pallet may be rotated to position the workpiece for oxide deposition, sputter deposition, and etching without removing the workpiece from the chamber.

13. A method for performing various processes on a workpiece located in a chamber, the chamber being sealable to create a low pressure environment in the chamber, the method comprising:
providing at least one workpiece on a rotating pallet in the chamber;
rotating the pallet to position the workpiece relative to a target for sputtering material onto the workpiece, a front side of the target being directed into the chamber;
rotating the pallet to position the workpiece substantially below a first induction coil substantially facing the pallet; and
energizing the first induction coil with RF energy to create a plasma only in a vicinity of the first induction coil for performing a process on the workpiece.

14. The method of claim 13 further comprising energizing a second induction coil located around the chamber for creating a plasma within the chamber to cause sputtering of material from the target onto the workpiece.

15. The method of claim 13 wherein energizing the first induction coil with RF energy to create a plasma only in a vicinity of the first induction coil for performing a process on the workpiece comprises performing etching of the workpiece.

16. The method of claim 13 wherein energizing the first induction coil with RF energy to create a plasma only in a vicinity of the first induction coil for performing a process on the workpiece comprises using the plasma for sputtering from the target onto the workpiece.

17. The method of claim 13 further comprising rotating the pallet to position the workpiece below a TEOS gas outlet in the chamber, and supplying TEOS gas through the TEOS gas outlet to deposit an oxide over a surface of the workpiece, such that the pallet is rotated to position the workpiece for oxide deposition, sputter deposition, and etching without removing the workpiece from the chamber.

18. The method of claim 13 wherein the first induction coil is a substantially flat coil having a substantially triangular shape, and the target has a substantially triangular shape.

19. The method of claim 13 wherein the pallet has a plurality of workpiece support areas for supporting a plurality of workpieces, wherein the pallet rotates to cause different workpieces to be under the target and the first induction coil.

20. The method of claim 13 wherein the target and induction coil are supported by a top wall of the chamber.

21. The method of claim 13 further comprising the workpiece having via holes, wherein the pallet is rotated to sputter material from the target into the via holes, followed by rotating the pallet under the first induction coil to etch pinch-off material at openings of the via holes.
